(19) United States
(12) Patent Application Publication
(10) Pub. No.: US 2026/0282219 A1
(43) Pub. Date: Sep. 17, 2026

(54) PRINTED WIRING BOARD

(71) Applicant: SUMITOMO ELECTRIC PRINTED CIRCUITS, INC., Shiga (JP)

(72) Inventors: Takuma HITOTSUMATSU, Shiga (JP); Makoto YAMAMOTO, Shiga (JP); Kou NOGUCHI, Shiga (JP); Masaki MIYABARA, Shiga (JP)

(73) Assignee: SUMITOMO ELECTRIC PRINTED CIRCUITS, INC., Shiga (JP)

(21) Appl. No.: 19/469,045

(22) PCT Filed: Mar. 31, 2023
(86) PCT No.: PCT/JP2023/013622

§ 371 Date: Sep. 25, 2025

(51) Int. Cl. H05K 1/03; H05K 3/28

(52) U.S. Cl. CPC H05K 1/0326; H05K 3/28; H05K 2201/09263; H05K 2201/09272

(57) ABSTRACT

The printed wiring board includes a base film having a main surface, a conductive pattern disposed on the main surface, and a coverlay including an adhesive layer disposed on the main surface so as to cover the conductive pattern and an insulating film disposed on the adhesive layer. The conductive pattern has a terminal portion. The coverlay is formed with an opening that penetrates the coverlay to expose an upper surface of the terminal portion. When an edge of the opening on a lower surface of the adhesive layer is defined as a first opening edge and an edge of the opening on a lower surface of the insulating film is defined as a second opening edge, a resin flow width (a distance between the first opening edge and the second opening edge) is 30% or less of a minimum value of a width of the first opening edge.

### TECHNICAL FIELD

The present disclosure relates to a printed wiring board.

### BACKGROUND ART

For example, WO 2016/147993 (PTL 1) describes a printed wiring board. The printed wiring board includes a base film, a conductive pattern, and an insulating layer. The base film has a main surface. The conductive pattern is disposed on the main surface of the base film. The conductive pattern includes a plurality of wiring portions arranged side by side in a direction perpendicular to the normal line of the main surface of the base film. The insulating layer is disposed on the main surface of the base film so as to cover the conductive pattern.

### CITATION LIST

### Patent Literature

PTL 1: WO 2016/147993

### SUMMARY OF INVENTION

A printed wiring board of the present disclosure includes a base film having a main surface, a conductive pattern disposed on the main surface, and a coverlay including an adhesive layer disposed on the main surface so as to cover the conductive pattern and an insulating film disposed on the adhesive layer. The conductive pattern has a terminal portion. The coverlay is formed with an opening that penetrates the coverlay to expose an upper surface of the terminal portion. When an edge of the opening on a lower surface of the adhesive layer is defined as a first opening edge and an edge of the opening on a lower surface of the insulating film is defined as a second opening edge, a resin flow width, which is a distance between the first opening edge and the second opening edge, is 30% or less of a minimum value of a width of the first opening edge.

### BRIEF DESCRIPTION OF DRAWINGS

FIG. 1 is a plan view of a printed wiring board 100.

FIG. 2 is a bottom view of printed wiring board 100.

FIG. 3 is a cross-sectional view taken along line III-III in FIG. 1.

FIG. 4 is a cross-sectional view taken along line IV-IV in FIG. 1.

FIG. 5 is a cross-sectional view taken along line V-V in FIG. 1.

FIG. 6 is a cross-sectional view taken along line VI-VI in FIG. 1.

FIG. 7 is a diagram illustrating a method of manufacturing printed wiring board 100.

FIG. 8 is a cross-sectional view of a printed wiring board 100 according to a modification.

### DETAILED DESCRIPTION

### Problem to be Solved by the Present Disclosure

A coverlay may be used as the insulating layer, for example. The coverlay includes an adhesive layer disposed on the main surface of the base film so as to cover the conductive pattern, and an insulating film disposed on the adhesive layer. In order to electrically connect the conductive pattern to the outside, the coverlay is formed with an opening to expose an upper surface of a terminal portion of the conductive pattern.

An opening edge of the opening on the lower surface of the adhesive layer is defined as a first opening edge, and an opening edge of the opening on the lower surface of the insulating film is defined as a second opening edge. When attaching the coverlay to the base film, a phenomenon called a resin flow may occur, in which the adhesive layer flows so that the first opening edge is located inside the second opening edge in a plan view. As a result of the resin flow, the distance (resin flow width) between the first opening edge and the second opening edge may become too large, which reduces the area of the upper surface of the conductive pattern used for electrical connection to the outside.

The present disclosure has been made in view of the problems of the prior art described above. More specifically, the present disclosure provides a printed wiring board capable of ensuring a connection area for a terminal portion of a conductive pattern.

### Advantageous Effect of the Present Disclosure

According to the printed wiring board of the present disclosure, it is possible to ensure a connection area for the terminal portion.

### DESCRIPTION OF EMBODIMENTS OF THE PRESENT DISCLOSURE

First, embodiments of the present disclosure will be described.
(1) A printed wiring board according to an embodiment includes a base film having a main surface, a conductive pattern disposed on the main surface, and a coverlay including an adhesive layer disposed on the main surface so as to cover the conductive pattern and an insulating film disposed on the adhesive layer. The conductive pattern has a terminal portion. The coverlay is formed with an opening that penetrates the coverlay to expose an upper surface of the terminal portion. When an edge of the opening on a lower surface of the adhesive layer is defined as a first opening edge and an edge of the opening on a lower surface of the insulating film is defined as a second opening edge, a resin flow width, which is a distance between the first opening edge and the second opening edge, is 30% or less of a minimum value of a width of the first opening edge. According to the printed wiring board of (1), it is possible to ensure the connection area for the terminal portion.
(2) In the printed wiring board of (1), the resin flow width may be 0 mm or more and 0.3 mm or less.
(3) In the printed wiring board of (1), the thickness of the insulating film may be 2 μm or more and 7 μm or less. According to the printed wiring board of (3), it is possible to further ensure the connection area for the terminal portion.
(4) In the printed wiring board of (1), the thickness of the adhesive layer between the upper surface of the conductive pattern and the lower surface of the insulating film may be 3 μm or more and 15 μm or less. According to the printed wiring board of (4), it is possible to ensure the connection area for the terminal portion while ensuring the adhesiveness between the adhesive layer and the insulating film.
(5) In the printed wiring board of (1), the thickness of the conductive pattern may be 30 μm or more and 150 μm or less. According to the printed wiring board of (5), it is possible to ensure the connection area for the terminal portion even when the resin flow is likely to occur.
(6) In the printed wiring board of (1), the conductive pattern may include a plurality of wiring portions. The normal line of the main surface may be in a first direction. Each of the plurality of wiring portions may extend in a second direction orthogonal to the first direction. The plurality of wiring portions may be arranged side by side in a third direction orthogonal to the first direction and the second direction. A distance between two adjacent wiring portions of the plurality of wiring portions may be 3 μm or more and 30 μm or less. According to the printed wiring board of (6), it is possible to ensure the connection area for the terminal portion even when the resin flow is likely to occur.
(7) In the printed wiring board of (1), the arithmetic average height of pimples and dimples on the upper surface of the insulating film may be 0.010 μm or more and 1.00 μm or less.
(8) In the printed wiring board of (1), the conductive pattern may include a plurality of wiring portions. The normal line of the main surface is in a first direction. Each of the plurality of wiring portions may be in a second direction orthogonal to the first direction. The plurality of wiring portions may be arranged side by side in a third direction orthogonal to the first direction and the second direction. A period of pimples or dimples on a portion of the upper surface of the insulating film located above the plurality of wiring portions is 0.80 times or more and 1.20 times or less a pitch between two adjacent wiring portions of the plurality of wiring portions.
(9) In the printed wiring board of (1) to (9), the insulating film may be formed of polyimide or liquid crystal polymer.

### Details of Embodiments of the Present Disclosure

Next, embodiments of the present disclosure will be described in detail with reference to the drawings. In the following drawings, the same or corresponding parts are denoted by the same reference numerals, and the description thereof will not be repeated. The printed wiring board according to the embodiment is defined as a printed wiring board 100.

### (Configuration of Printed Wiring Board 100)

Hereinafter, the configuration of printed wiring board 100 will be described.

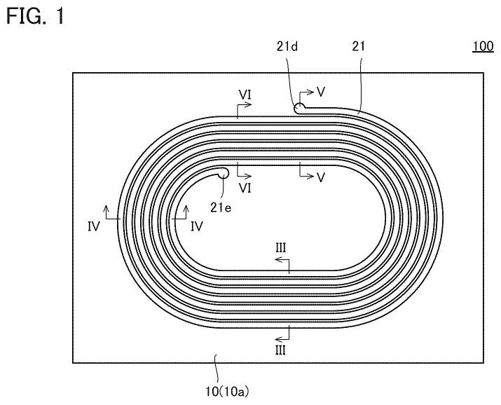

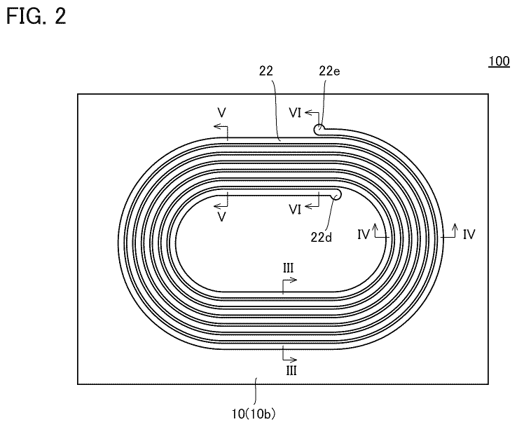

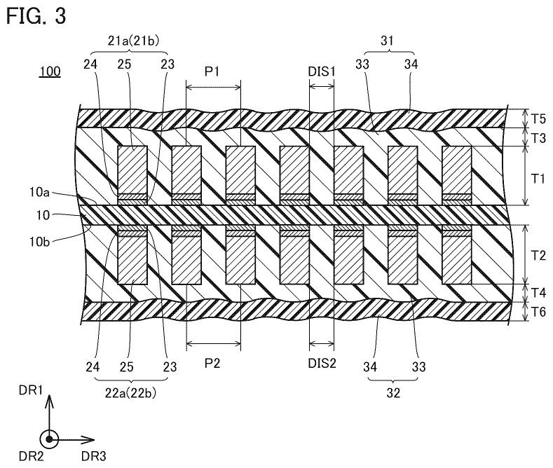

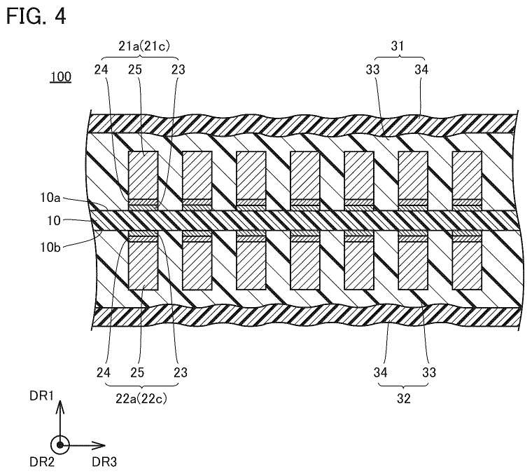

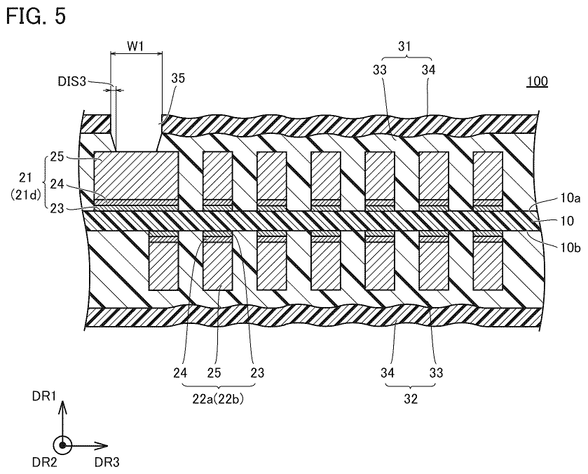

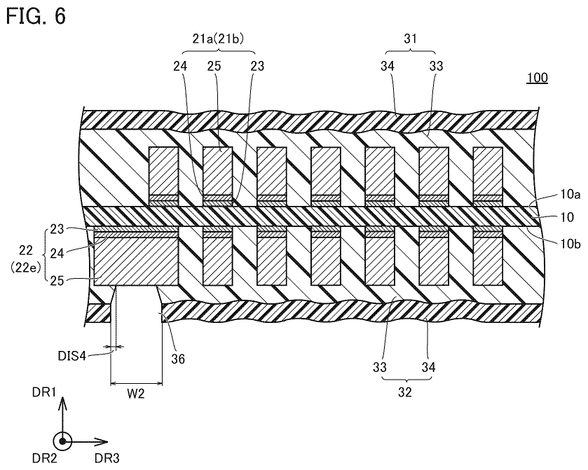

FIG. 1 is a plan view of printed wiring board 100. FIG. 2 is a bottom view of printed wiring board 100. Printed wiring board 100 illustrated in FIG. 2 is viewed from the opposite side of FIG. 1. A coverlay 31 and a coverlay 32 are not illustrated in FIGS. 1 and 2. FIG. 3 is a cross-sectional view taken along line III-III in FIG. 1. FIG. 4 is a cross-sectional view taken along line IV-IV in FIG. 1. FIG. 5 is a cross-sectional view taken along line V-V in FIG. 1. FIG. 6 is a cross-sectional view taken along line VI-VI in FIG. 1. As illustrated in FIGS. 1 to 6, printed wiring board 100 includes a base film 10, a conductive pattern 21, a conductive pattern 22, a coverlay 31, and a coverlay 32.

Base film 10 has a main surface 10a and a main surface 10b. Main surface 10a and main surface 10b are end surfaces in the thickness direction of base film 10. Main surface 10b is opposite to main surface 10a. Base film 10 is formed of a flexible insulating material. Base film 10 is formed of, for example, polyimide or liquid crystal polymer. The normal direction of main surface 10a (main surface 10b) is defined as a first direction DR1.

Conductive pattern 21 is disposed on main surface 10a. Conductive pattern 21 is spirally wound in a plan view. Conductive pattern 21 includes a plurality of wiring portions 21a.

The plurality of wiring portions 21a may be a plurality of linear portions 21b or a plurality of curved portions 21c. Linear portion 21b extends linearly in a plan view. Curved portion 21c extends in a curved shape in a plan view. The extending direction of wiring portion 21a (linear portion 21b, curved portion 21c) is defined as a second direction DR2. When wiring portion 21a is a curved portion 21c, second direction DR2 is a tangential direction of curved portion 21c.

The plurality of wiring portions 21a (linear portions 21b and curved portions 21c) are arranged side by side with an interval interposed therebetween in third direction DR3. Third direction DR3 is a direction orthogonal to first direction DR1 and second direction DR2.

Conductive pattern 22 is disposed on main surface 10b. Conductive pattern 22 is spirally wound in a plan view. Conductive pattern 21 includes a plurality of wiring portions 22a.

The plurality of wiring portions 22a may be a plurality of linear portions 22b or a plurality of curved portions 22c. Linear portion 22b extends linearly in a plan view. Curved portion 22c extends in a curved shape in a plan view. Wiring portion 22a (linear portion 22b, curved portion 22c) extends in second direction DR2. When wiring portion 22a is a curved portion 22c, second direction DR2 is a tangential direction of curved portion 22c. The plurality of wiring portions 22a (linear portions 22b and curved portions 22c) are arranged side by side with an interval interposed therebetween in third direction DR3.

Conductive pattern 21 has a land 21d at one end and a land 21e at the other end. Land 21d and land 21e are located on the outermost circumference and the innermost circumference of conductive pattern 21, respectively. Conductive pattern 22 has a land 22d at one end and a land 22e at the other end. Land 22d and land 22e are located on the innermost circumference and the outermost circumference of conductive pattern 22, respectively. Land 21d and land 22e are terminal portions to be electrically connected to the outside. Land 21e and land 22d overlap each other in a plan view.

Each of conductive pattern 21 and conductive pattern 22 is formed by, for example, a semi-additive process. More specifically, each of conductive pattern 21 and conductive pattern 22 includes a seed layer 23, an electroless plating layer 24, and an electrolytic plating layer 25. However, each of conductive pattern 21 and conductive pattern 22 may be formed by a subtractive process.

Seed layer 23 is disposed on the main surface (main surface 10a, main surface 10b) of base film 10. Seed layer 23 is, for example, a sputtered layer (a layer formed by a sputtering method). Seed layer 23 includes, for example, a first layer and a second layer. The first layer is disposed on the main surface (main surface 10a, main surface 10b) of base film 10. The second layer is disposed on the first layer. For example, the first layer is formed of nickel-chromium alloy, and the second layer is formed of copper.

Electroless plating layer 24 is formed by electroless plating process. Electroless plating layer 24 is disposed on seed layer 23. Electroless plating layer 24 is formed of copper, for example. Electrolytic plating layer 25 is formed by electrolytic plating process. Electrolytic plating layer 25 is disposed on electroless plating layer 24. Electrolytic plating layer 25 is formed of copper, for example.

Although not illustrated in the drawing, base film 10 is formed with a through hole 10c. Through hole 10c penetrates base film 10 in the thickness direction. Through hole 10c overlaps land 21e and land 22d in the plan view. Electroless plating layer 24 is also disposed on the inner wall surface of through hole 10c. Electrolytic plating layer 25 is also embedded in through hole 10c. Thus, conductive pattern 21 and conductive pattern 22 are electrically connected to each other. When a voltage is applied between land 21d and land 22e, a current spirally flows through conductive pattern 21 and conductive pattern 22, which generates a magnetic field. From another viewpoint, printed wiring board 100 is a coil unit.

The thickness of conductive pattern 21 is defined as a thickness T1. The thickness of conductive pattern 22 is defined as a thickness T2. Each of thickness T1 and thickness T2 is, for example, 30 μm or more and 150 μm or less. The distance between two adjacent wiring portions 21a is defined as a distance DIS1. The distance between two adjacent wiring portions 22a is defined as a distance DIS2. Each of distance DIS1 and distance DIS2 is, for example, 3 μm or more and 30 μm or less.

Each of coverlay 31 and coverlay 32 includes an adhesive layer 33 and an insulating film 34. Adhesive layer 33 is formed of an adhesive material. Adhesive layer 33 of coverlay 31 is disposed on main surface 10a so as to cover conductive pattern 21. Adhesive layer 33 of coverlay 32 is disposed on main surface 10b so as to cover conductive pattern 22. Insulating film 34 is disposed on adhesive layer 33. Insulating film 34 is formed of, for example, polyimide or liquid crystal polymer.

The thickness of adhesive layer 33 of coverlay 31 between the upper surface of conductive pattern 21 and the lower surface of insulating film 34 of coverlay 31 is defined as a thickness T3. The thickness of adhesive layer 33 of coverlay 32 between the upper surface of conductive pattern 22 and the lower surface of insulating film 34 of coverlay 32 is defined as a thickness T4. Each of thickness T3 and thickness T4 is, for example, 3 μm or more and 15 μm or less.

The thickness of insulating film 34 of coverlay 31 is defined as a thickness T5. The thickness of insulating film 34 of coverlay 32 is defined as a thickness T6. Each of thickness T5 and thickness T6 is, for example, 2 μm or more and 7 μm or less.

The arithmetic average height (Sa) of pimples and dimples on the upper surface of insulating film 34 is 0.010 μm or more and 1.00 μm or less. The arithmetic average height of pimples and dimples on the upper surface of insulating film 34 is measured using a laser microscope. The definition of the arithmetic mean height is defined in ISO 25178.

The upper surface of insulating film 34 is formed with pimples and dimples in third direction DR3. A pitch between two adjacent wiring portions 21a is defined as a pitch P1. A pitch between two adjacent wiring portions 22a is defined as a pitch P2. A period of pimples or dimples on a portion of the upper surface of insulating film 34 located above the plurality of wiring portions 21a in third direction DR3 is, for example, 0.80 times or more and 1.20 times or less pitch P1. A period of pimples or dimples on a portion of the upper surface of insulating film 34 located above the plurality of wiring portions 22a in third direction DR3 is, for example, 0.80 times or more and 1.20 times or less pitch P2.

The period of pimples or dimples on the upper surface of insulating film 34 in third direction DR3 may be obtained as a distance between two adjacent pimples by measuring the upper surface of insulating film 34 with a laser microscope at a magnification power of 20 times or more and 50 times or less.

Coverlay 31 is formed with an opening 35. Opening 35 penetrates coverlay 31 (adhesive layer 33 and insulating film 34) in the thickness direction. The upper surface of land 21d is exposed from opening 35. Coverlay 32 is formed with an opening 36. Opening 36 penetrates coverlay 32 (adhesive layer 33 and insulating film 34) in the thickness direction. The upper surface of land 22e is exposed from opening 36.

The width of opening 35 on insulating film 34 is defined as a width W1, and the width of opening 36 on insulating film 34 is defined as a width W2. Width W1 and width W2 are measured on the lower surface of insulating film 34. The distance between the opening edge of opening 35 on the lower surface of adhesive layer 33 and the opening edge of opening 35 on the lower surface of insulating film 34 is defined as a distance DIS3. The distance between the opening edge of opening 36 on the lower surface of adhesive layer 33 and the opening edge of opening 36 on the lower surface of insulating film 34 is defined as a distance DIS4. Distance DIS3 and distance DIS4 correspond to the resin flow width. Width W1, width W2, distance DIS3 and distance DIS4 are measured from a 2D image of printed wiring board 100 which is acquired using a microscope.

Distance DIS3 is 30% or less of a minimum value of width W1. In other words, the value obtained by dividing distance DIS3 by the minimum value of width W1 is 0.3 or less. Distance DIS4 is 30% or less of a minimum value of width W2. In other words, the value obtained by dividing distance DIS4 by the minimum value of width W2 is 0.30 or less. Each of distance DIS3 and distance DIS4 is, for example, 0 mm or more and 0.3 mm or less.

### (Method for Manufacturing Printed Wiring Board 100)

Hereinafter, a method of manufacturing printed wiring board 100 will be described.

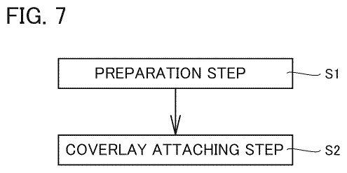

FIG. 7 is a diagram illustrating a method of manufacturing printed wiring board 100. As illustrated in FIG. 7, the method of manufacturing printed wiring board 100 includes a preparation step S1 and a coverlay attaching step S2. The coverlay attaching step S2 is performed after the preparation step S1.

In the preparation step S1, base film 10, coverlay 31, and coverlay 32 are prepared. In base film 10 prepared in the preparation step S1, conductive pattern 21 is disposed on main surface 10a, and conductive pattern 22 is disposed on main surface 10b. In coverlay 31 and coverlay 32 prepared in the preparation step S1, the adhesive material constituting adhesive layer 33 is uncured. Coverlay 31 is formed with an opening 35 by punching, and coverlay 32 is formed with an opening 36 by punching, for example.

In the coverlay attaching step S2, coverlay 31 and coverlay 32 are attached to base film 10. In the coverlay attaching step S2, firstly, coverlay 31 is disposed on main surface 10a in such a manner that adhesive layer 33 covers conductive pattern 21, and coverlay 32 is disposed on main surface 10b in such a manner that adhesive layer 33 covers conductive pattern 22.

Thereafter, coverlay 31 and coverlay 32 are hot-pressed onto base film 10. At this time, a cushion material is interposed between a hot pressing apparatus and coverlay 31 and coverlay 32. Thus, the adhesive material constituting adhesive layer 33 is cured, and coverlay 31 and coverlay 32 are attached to base film 10.

The cushion material is formed of a resin. The glass transition temperature of the resin constituting the cushion material is lower than the heating temperature in the hot pressing. Therefore, during the hot pressing described above, insulating film 34 deforms along the shape of the plurality of wiring portions 21a (wiring portions 22a), which forms periodic pimples and dimples on a portion of the upper surface of insulating film 34 located above the plurality of wiring portions 21a (wiring portions 22a) in third direction DR3. Thus, printed wiring board 100 having the configuration illustrated in FIGS. 1 to 6 is formed.

### <Modification>

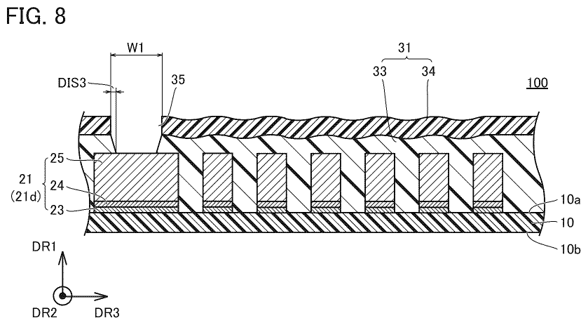

FIG. 8 is a cross-sectional view of a printed wiring board 100 according to a modification. As illustrated in FIG. 8, printed wiring board 100 may not include conductive pattern 22 and coverlay 32.

### (Effects of Printed Circuit Board 100)

Hereafter, the effects of printed wiring board 100 will be described.

In printed wiring board 100, the resin flow width is small. More specifically, in printed wiring board 100, distance DIS3 is 30% or less of the minimum value of width W1, and distance DIS4 is 30% or less of the minimum value of width W2. Therefore, in printed wiring board 100, the area of the upper surface of land 21d and land 22d to be electrically connected to the outside is ensured.

As the aspect ratio of conductive pattern 21 and conductive pattern 22 increases (in other words, as thickness T1 and thickness T2 increase), or as the density of conductive pattern 21 and conductive pattern 22 increases (in other words, as distance DIS1 and distance DIS2 decrease), the resin flow is likely to occur when attaching coverlay 31 and coverlay 32.

However, in printed wiring board 100, thickness T5 and thickness T6 are as small as 2 μm or more and 7 μm or less. In addition, in printed wiring board 100, a cushion material which is easily softened (which has a low glass transition temperature) is disposed between the hot pressing apparatus and coverlay 31 and coverlay 32 when the hot pressing is being performed. Therefore, in printed wiring board 100, insulating film 34 is deformed during the hot pressing, and thereby, distance DIS3 and distance DIS4 are less likely to increase due to the resin flow.

As thickness T3 and thickness T4 become larger, the pressing force to be applied during the hot pressing becomes smaller. Since the resin flow is less likely to occur as the pressing force to be applied during the hot pressing is smaller, when thickness T3 and thickness T4 become larger, it is easier to ensure the area of the upper surface of land 21d and land 22d to be electrically connected to the outside.

On the other hand, as thickness T3 and thickness T4 become smaller, the interface between adhesive layer 33 and insulating film 34 becomes closer to the neutral axis of printed wiring board 100 when bent, which makes it easier to ensure the adhesiveness between adhesive layer 33 and insulating film 34 when bent. When thickness T3 and thickness T4 are 3 μm or more and 15 μm or less, it is possible to ensure the area of the tipper surface of land 21d and land 22d to be electrically connected to the outside while ensuring the adhesiveness between adhesive layer 33 and insulating film 34.

### Example

Samples 1 to 72 were prepared to evaluate the relationship between thickness T1 (thickness T2), thickness T3 (thickness T4), thickness T5 (thickness T6), distance DIS1 (distance DIS2), and distance DIS3 (distance DIS4). The details of samples 1 to 72 are listed in Tables 1, 2 and 3. In samples 1 to 72, distance DIS3 was measured by varying thickness T1, thickness T3, thickness T5, and distance DIS1. In addition, in samples 1 to 72, width W1 was set to a fixed value (μm).

TABLE 1

| | Thickness T5 | Thickness T3 | Thickness T1 | Distance DIS1 | Distance DIS3 |
|---|---|---|---|---|---|
| Sample | (μm) | (μm) | (μm) | (μm) | (mm) |
| 1 | 2 | 14 | 40 | 30 | 0.04 |
| 2 | 2 | 9 | 40 | 20 | 0.05 |
| 3 | 2 | 7 | 40 | 10 | 0.06 |
| 4 | 2 | 4 | 40 | 5 | 0.07 |
| 5 | 2 | 12 | 90 | 30 | 0.05 |
| 6 | 2 | 9 | 90 | 20 | 0.07 |
| 7 | 2 | 6 | 90 | 10 | 0.11 |
| 8 | 2 | 4 | 90 | 5 | 0.12 |
| 9 | 2 | 11 | 120 | 30 | 0.07 |
| 10 | 2 | 9 | 120 | 20 | 0.08 |
| 11 | 2 | 6 | 120 | 10 | 0.12 |
| 12 | 2 | 4 | 120 | 5 | 0.18 |
| 13 | 3 | 14 | 40 | 30 | 0.04 |
| 14 | 3 | 10 | 40 | 20 | 0.06 |
| 15 | 3 | 8 | 40 | 10 | 0.07 |
| 16 | 3 | 4 | 40 | 5 | 0.09 |
| 17 | 3 | 13 | 90 | 30 | 0.06 |
| 18 | 3 | 10 | 90 | 20 | 0.08 |
| 19 | 3 | 7 | 90 | 10 | 0.12 |
| 20 | 3 | 4 | 90 | 5 | 0.14 |
| 21 | 3 | 12 | 120 | 30 | 0.08 |
| 22 | 3 | 9 | 120 | 20 | 0.10 |
| 23 | 3 | 7 | 120 | 10 | 0.15 |
| 24 | 3 | 4 | 120 | 5 | 0.20 |

TABLE 2

| | Thickness T5 | Thickness T3 | Thickness T1 | Distance DIS1 | Distance DIS3 |
|---|---|---|---|---|---|
| Sample | (μm) | (μm) | (μm) | (μm) | (mm) |
| 25 | 5 | 13 | 40 | 30 | 0.05 |
| 26 | 5 | 10 | 40 | 20 | 0.07 |
| 27 | 5 | 6 | 40 | 10 | 0.08 |
| 28 | 5 | 4 | 40 | 5 | 0.10 |
| 29 | 5 | 15 | 90 | 30 | 0.06 |
| 30 | 5 | 10 | 90 | 20 | 0.08 |
| 31 | 5 | 7 | 90 | 10 | 0.12 |
| 32 | 5 | 4 | 90 | 5 | 0.15 |
| 33 | 5 | 10 | 120 | 30 | 0.08 |
| 34 | 5 | 7 | 120 | 20 | 0.10 |
| 35 | 5 | 5 | 120 | 10 | 0.15 |
| 36 | 5 | 4 | 120 | 5 | 0.20 |
| 37 | 7 | 14 | 40 | 30 | 0.06 |
| 38 | 7 | 10 | 40 | 20 | 0.07 |
| 39 | 7 | 8 | 40 | 10 | 0.10 |
| 40 | 7 | 4 | 40 | 5 | 0.13 |
| 41 | 7 | 15 | 90 | 30 | 0.08 |
| 42 | 7 | 10 | 90 | 20 | 0.12 |
| 43 | 7 | 7 | 90 | 10 | 0.15 |
| 44 | 7 | 4 | 90 | 5 | 0.20 |
| 45 | 7 | 10 | 120 | 30 | 0.10 |
| 46 | 7 | 7 | 120 | 20 | 0.17 |
| 47 | 7 | 5 | 120 | 10 | 0.20 |
| 48 | 7 | 4 | 120 | 5 | 0.30 |

TABLE 3

| | Thickness T5 | Thickness T3 | Thickness T1 | Distance DIS1 | Distance DIS3 |
|---|---|---|---|---|---|
| Sample | (μm) | (μm) | (μm) | (μm) | (mm) |
| 49 | 12.5 | 10 | 40 | 30 | 0.10 |
| 50 | 12.5 | 8 | 40 | 20 | 0.25 |
| 51 | 12.5 | 3 | 40 | 10 | 0.30 |
| 52 | 12.5 | 2 | 40 | 5 | 0.36 |
| 53 | 12.5 | 6 | 90 | 30 | 0.25 |
| 54 | 12.5 | 4 | 90 | 20 | 0.30 |
| 55 | 12.5 | 3 | 90 | 10 | 0.40 |
| 56 | 12.5 | 2 | 90 | 5 | 0.50 |
| 57 | 12.5 | 4 | 120 | 30 | 0.30 |
| 58 | 12.5 | 2 | 120 | 20 | 0.40 |
| 59 | 12.5 | 2 | 120 | 10 | 0.50 |
| 60 | 12.5 | 1 | 120 | 5 | 0.64 |
| 61 | 25 | 10 | 40 | 30 | 0.15 |
| 62 | 25 | 8 | 40 | 20 | 0.30 |
| 63 | 25 | 3 | 40 | 10 | 0.40 |
| 64 | 25 | 2 | 40 | 5 | 0.50 |
| 65 | 25 | 7 | 90 | 30 | 0.30 |
| 66 | 25 | 4 | 90 | 20 | 0.35 |
| 67 | 25 | 3 | 90 | 10 | 0.50 |
| 68 | 25 | 2 | 90 | 5 | 0.70 |
| 69 | 25 | 3 | 120 | 30 | 0.40 |
| 70 | 25 | 2 | 120 | 20 | 0.50 |
| 71 | 25 | 2 | 120 | 10 | 0.60 |
| 72 | 25 | 1 | 120 | 5 | 0.85 |

When thickness T1 is 30 μm or more and 150 μm or less, it is defined as condition A. When thickness T3 is 3 μm or more and 15 μm or less, it is defined as condition B. When thickness T5 is 2 μm or more and 7 μm or less, it is defined as condition C. When distance DIS1 is 3 μm or more and 30 μm or less, it is defined as condition D.

In samples 1 to 51, 53, 54, 57, 61, 62, and 65, all of conditions A to D were satisfied. On the other hand, in samples 52, 55, 56, 58 to 60, 63, 64, and 66 to 72, at least one of conditions A to D was not satisfied.

In samples 1 to 51, 53, 54, 57, 61, 62, and 65, distance DIS3 was 0 mm or more and 0.3 mm or less (in other words, distance DIS3 is 30% or less of width W1). On the other hand, in samples 52, 55, 56, 58 to 60, 63, 64, and 66 to 72, distance DIS3 was greater than 0.3 mm.

From this comparison, it is obvious that distance DIS3 (distance DIS4) can be set to 0 mm or more and 0.3 mm or less (in other words, 30% or less of width W1 (width W2)) by appropriately adjusting thickness T1 (thickness T2), thickness T3 (thickness T4), thickness T5 (thickness T6), and distance DIS1 (distance DIS2).

It should be understood that the embodiments disclosed herein have been presented for the purpose of illustration and description but not limited in all aspects. It is intended that the scope of the present invention is not limited to the description above but defined by the scope of the claims and encompasses all modifications equivalent in meaning and scope to the claims.

### REFERENCE SIGNS LIST

100: printed wiring board; 10: base film; 10a: main surface; 10b: main surface; 10c: through hole; 21: conductive pattern; 21a wiring portion; 21b: linear portion; 21c: curved portion; 21d, 21e land; 22: conductive pattern; 22a: wiring portion; 22b: linear portion; 22c: curved portion; 22d, 22e: land; 23: seed layer; 24: electroless plating layer; 25: electrolytic plating layer; 31, 32: coverlay; 33: adhesive layer; 34: insulating film; 35, 36: opening; DIS1. DIS2, DIS3, DIS4: distance; DR1: first direction; DR2: second direction; DR3: third direction; P1, P2: pitch; S1: preparation step; S2: coverlay attaching step; T1, T2, T3, T4, T5, T6: thickness; W1, W2: width.

1. A printed wiring board comprising:
a base film having a main surface;
a conductive pattern disposed on the main surface; and
a coverlay including an adhesive layer disposed on the main surface so as to cover the conductive pattern and an insulating film disposed on the adhesive layer,
the conductive pattern has a terminal portion,
the coverlay is formed with an opening that penetrates the coverlay to expose an upper surface of the terminal portion,
when an edge of the opening on a lower surface of the adhesive layer is defined as a first opening edge and an edge of the opening on a lower surface of the insulating film is defined as a second opening edge, a resin flow width, which is a distance between the first opening edge and the second opening edge, is 30% or less of a minimum value of a width of the first opening edge.

2. The printed wiring board according to claim 1, wherein
the resin flow width is 0 mm or more and 0.3 mm or less.

3. The printed wiring board according to claim 1, wherein
the thickness of the insulating film is 2 μm or more and 7 μm or less.

4. The printed wiring board according to claim 1, wherein
the thickness of the adhesive layer between an upper surface of the conductive pattern and the lower surface of the insulating film is 3 μm or more and 15 μm or less.

5. The printed wiring board according to claim 1, wherein
the thickness of the conductive pattern is 30 μm or more and 150 μm or less.

6. The printed wiring board according to claim 1, wherein
the conductive pattern includes a plurality of wiring portions,
the normal line of the main surface is in a first direction,
each of the plurality of wiring portions extends in a second direction orthogonal to the first direction,
the plurality of wiring portions are arranged side by side in a third direction orthogonal to the first direction and the second direction, and
a distance between two adjacent wiring portions of the plurality of wiring portions is 3 μm or more and 30 μm or less.

7. The printed wiring board according to claim 1, wherein
the arithmetic average height of pimples and dimples on an upper surface of the insulating film is 0.010 μm or more and 1.00 μm or less.

8. The printed wiring board according to claim 1, wherein
the conductive pattern includes a plurality of wiring portions,
the normal line of the main surface is in a first direction,
each of the plurality of wiring portions extends in a second direction orthogonal to the first direction,
the plurality of wiring portions are arranged in a third direction orthogonal to the first direction and the second direction, and
a period of pimples or dimples on a portion of an upper surface of the insulating film located above the plurality of wiring portions is 0.80 times or more and 1.20 times or less a pitch between two adjacent wiring portions of the plurality of wiring portions.

9. The printed wiring board according to claim 1, wherein
the insulating film is formed of polyimide or liquid crystal polymer.
